(19) United States
(12) Patent Application Publication
(10) Pub. No.: US 2025/0344851 A1
(43) Pub. Date: Nov. 13, 2025

(54) RACK SYSTEM AND MODULAR AUDIO EQUIPMENT

(71) Applicant: Superlative Instruments, Cambridge, MA (US)

(72) Inventor: Benjamin Stamas, Cambridge, MA (US)

(21) Appl. No.: 19/204,086

(22) Filed: May 9, 2025

Related U.S. Application Data
(60) Provisional application No. 63/645,567, filed on May 10, 2024.

(51) Int. Cl. A47B 81/00; A47B 47/00; H05K 7/14

(52) U.S. Cl. CPC A47B 81/00; A47B 47/00; H05K 7/14

(57) ABSTRACT

Modular audio equipment may be configured with features and/or physical dimensions allowing it to be used comfortably in hand, in a standalone configuration, and/or integrated into a rack system for use individually and in combination with other modules. The rack system may include features for providing power to, and/or data communication between, modules mounted thereto; however, a module may be accessible individually (e.g., wirelessly or with a dedicated cable) while mounted to the rack. The rack system may include intelligence for identifying a module and its position in the rack system. The rack system may convey this information to a computing system and allow the computing system to build a virtual representation or “digital twin” of the rack system and mounted modules. A user may control the modules remotely via a graphical user interface of the computing device showing the virtual representation of the rack system and modules.

### CROSS-REFERENCE TO RELATED APPLICATIONS

This application claims the benefit under 35 U.S.C. § 119(e) to U.S. Provisional Application Ser. No. 63/645,567, entitled RACK SYSTEM AND MODULAR AUDIO EQUIPMENT, filed May 10, 2024, the entire content of which is incorporated herein by reference.

### BACKGROUND

Audio equipment includes musical instruments such as synthesizers, keyboards, sequencers, effects, preamplifiers, power amplifiers, speakers, mixers, analog and digital recorders, digital audio workstations, analog-to-digital and digital-to-analog converters, power supplies and conditioners, and the like. Some audio equipment may be configured for standalone use; for example, on a floor, desktop, or shelf. Some studio equipment may be configured for mounting in one of a variety of standardized racks.

### BRIEF DESCRIPTION OF THE DRAWINGS

Objects, aspects, features, and advantages of embodiments disclosed herein will become more fully apparent from the following detailed description, the appended claims, and the accompanying figures in which like reference numerals identify similar or identical elements. Reference numerals that are introduced in the specification in association with a figure may be repeated in one or more subsequent figures without additional description in the specification in order to provide context for other features, and not every element may be labeled in every figure. The drawings are not necessarily to scale, emphasis instead being placed upon illustrating embodiments, principles and concepts. The drawings are not intended to limit the scope of the claims included herewith.

FIG. 1 illustrates an example audio equipment module, according to embodiments of the present disclosure.

FIG. 2A illustrates a front view of an example module showing a control surface and rails, according to embodiments of the present disclosure.

FIG. 2B illustrates a side view of the example module, according to embodiments of the present disclosure.

FIG. 2C illustrates a side view of the example module, according to embodiments of the present disclosure.

FIG. 3A illustrates a first view of an example module detailing a corner and screw hole, according to embodiments of the present disclosure.

FIG. 3B illustrates a second view of an example module detailing a corner and screw hole with a screw, according to embodiments of the present disclosure.

FIG. 4A illustrates a side view of a first example of a module in a standalone configuration, according to embodiments of the present disclosure.

FIG. 4B illustrates a corner view of the first example of module in the standalone configuration, according to embodiments of the present disclosure.

FIG. 4C illustrates a side view of a second example of a module in a standalone configuration, according to embodiments of the present disclosure.

FIG. 4D illustrates a corner view a second example of the module in the standalone configuration, according to embodiments of the present disclosure.

FIG. 5A illustrates an example rack and audio equipment module, according to embodiments of the present disclosure.

FIG. 5B illustrates the example audio equipment module showing a first and second connector, according to embodiments of the present disclosure.

FIG. 5C illustrates the example rack with the mounting rails and arms disassembled, according to embodiments of the present disclosure.

FIG. 5D illustrates a detailed cross section of the example rack and audio equipment module, according to embodiments of the present disclosure.

FIG. 5E illustrates a detailed view of example rack and audio equipment module, according to embodiments of the present disclosure.

FIG. 6A illustrates a first view of an example rack with modules installed, according to embodiments of the present disclosure.

FIG. 6B illustrates a second view of an example rack with modules installed, according to embodiments of the present disclosure.

FIG. 6C illustrates a third view of an example rack with modules installed and an external digital connection, according to embodiments of the present disclosure.

FIGS. 6D and 6E illustrate views of an example rack further detailing various indicators and connectors, according to embodiments of the present disclosure.

FIG. 7A illustrates a first view of an example rack system open for use, according to embodiments of the present disclosure.

FIG. 7B illustrates a second view of the example rack system open for use, according to embodiments of the present disclosure.

FIG. 7C illustrates the example rack system closed for transit or storage, according to embodiments of the present disclosure.

FIG. 7D illustrates an example of a rack pane mounted using a handle/stand assembly of the rack system, according to embodiments of the present disclosure.

FIG. 7E illustrates an example of a rack pane mounted using a joint of the rack system, according to embodiments of the present disclosure.

FIG. 8 is a conceptual diagram illustrating components of the rack system, according to embodiments of the present disclosure.

FIG. 9 is a flowchart illustrating example operations of a power-on sequence of the rack system, according to embodiments of the present disclosure.

FIG. 10 is a block diagram conceptually illustrating example components of a system, according to embodiments of the present disclosure.

### DETAILED DESCRIPTION

Audio equipment may be configured in a variety of form factors. Some audio equipment may be configured for standalone use. Examples of standalone audio equipment may include configurations for desktop, stand, or shelf use (e.g., keyboards, mixing consoles, etc.), floor use (e.g., effects pedals/“stomp boxes,” direct input (“DI”) units, etc.), and handheld use (e.g., relatively small musical instrument digital interface (“MIDI”) controllers, synthesizers, drum machines, sequencers, etc.).

Some audio equipment may be rack mountable. Rack-mountable audio equipment may include mechanical and/or electrical features configured to fit and/or attach to one or more standardized rack systems. Standardized rack systems include the 19-inch rack (e.g., as also used for other electronic equipment such as computer servers), 500-series format, and Eurorack. Each rack system has benefits and drawbacks. For example, audio equipment configured for mounting in a 19-inch rack may have a limited area available for user access. The 19-inch rack standard is specified in “units” 1.75″ tall; thus, a single-unit module will have an exposed front side measuring 19×1.75″, a 2-unit module will have an exposed front side measuring 19×3.5″, and so on. Equipment installed in a 19-inch rack is typically stacked vertically with a front side exposed for observation/control of the equipment, and a back side configured for cable connections and/or other, generally less frequent, access; however, the top, bottom, and side surfaces are typically covered by adjacent equipment and/or the rack itself. This limits the area available for buttons, switches, knobs, sliders, input/output connections, and/or display indicators (e.g., lights, LCD screens, etc.). Moreover, while some equipment configured for the 19-inch rack standard may be useable when not installed in a rack (e.g., resting unattached on a desktop or other music equipment), it is neither convenient nor comfortable for handheld use, and useability remains hampered by the limited control surface.

Equipment configured for the 500-series format may suffer from the same limited control surface. The 500-series format has physical dimensions of 5.25″ high (e.g., three 19-rack standard units) and multiples of 1.5″ wide; thus, a single-unit 500-series module will be 1.5″ wide, a 2-unit module will be 3″ wide, and so on. The 500-series format also includes a 15-pin edge connector on the rear of the module, with corresponding physical and electrical specifications. Thus, in addition to the limited control surface, a 500-series module cannot be used standalone; rather, it is installed in a chassis that receives the edge connector to supply electrical power and provide input/output connections. Similarly, equipment configured for the Eurorack format also conform to physical and electrical standards that preclude standalone use; for example, a Eurorack module is typically an exposed-back bare circuit board that connects to a case via a 10- or 16-pin ribbon cable that supplies power to the module. The 19-inch, 500-series, and Eurorack formats/standards also require line power and line voltage (e.g., 120 volts alternating current (VAC)). These power requirements hamper or even prevent powering a unit or units with batteries, restricting portability and limiting use cases and environments where individual units and/or combinations of units may be used. Moreover, none of these rack systems or standards afford a method for digital communication and control (USB, serial, MIDI, etc.) between the rack and the audio equipment, or between pieces of audio equipment within the rack.

Offered herein are a rack system and audio equipment that overcome the limitations of the existing formats for audio equipment. The audio equipment may be configured as modules that can be mounted to the rack system (e.g., for integration with other modules), mounted to a stand for standalone use (e.g., on a desktop/tabletop), or removed from the rack/stand for handheld use. The modules may possess a dual-powering scheme, allowing them to draw power from the rack system and/or from a cable. Similarly, the modules may send and receive data via the rack and/or from a cable. The rack system may integrate with a computing device. The rack system may have features that allow it to determine the position of modules mounted to the rack and provide the position information to the computing device. This may allow the computing device to present a virtual representation of the modules that a user can use to remotely control the individual modules from a graphical user interface of the computing system.

In some implementations, a modular audio equipment unit (referred to hereafter as a “module”) may have physical features configured for comfortable handheld use. Such features may include rounded corners, chamfered edges, and/or mounting rails. The mounting rails may protrude from the module at opposite ends (e.g., upper and lower edges of the module) and extend from the left side to the right side of the module. The left and right ends of one or both of the mounting rails may be rounded (e.g., with a radius parallel to a plane extending from the upper mounting rail to the lower mounting rail). The mounting rails may be recessed with respect to a (user-facing) control surface and/or a back surface. A mounting rail that is recessed with respect to the control surface may allow for mounting screws to remain flush or recessed with respect to the control surface when the module is mounted to a rack (e.g., with other modules) or a stand (e.g., for standalone use). A mounting rail may include one or more connectors to, for example, mate with a corresponding connector of a rack when the module is mounted thereto as described below.

The control surface may be configured with various control features such as buttons, switches, knobs, sliders, selectors, etc. The control surface may be configured with various input/output connections such as connectors for patch cables (e.g., to convey analog audio signals), control voltage (CV) and gate signals (e.g., for controlling analog synthesizers), MIDI signals, digital control signals (e.g., USB), etc. The control surface may be configured with one or more various types of indicator and/or display such as a light-emitting diode (LED), mechanical and/or digital meter, liquid-crystal display (LCD), touchscreen, etc. The control surface may be accessible for observation and/or manipulation when mounted to a rack, mounted to a standalone stand or feet, and/or held in the hand. For example, when held in the hand, the module may be operated similar to a tablet computer (e.g., with the thumbs, one hand hold and one hand operating, etc.). The rounded corners, particularly at the ends of the lower mounting rail, prevent any sharp corners from digging into a hand of the user. Similarly, left and right back-facing edges of a module (e.g., edges along surfaces facing down when a module is laid flat on a table), may be rounded and/or chamfered. Similarly, front-and/or back-facing edges of the body of the module may be rounded and/or chamfered. The edges of the mounting rail other than the corners, however, may be left angular or only slightly rounded (e.g., a radius of less than a few millimeters) to provide a surface area on the back-facing surface for mating with a rack.

Modules may be configured with certain standard dimensions; for example, a distance from an upper mounting rail to the lower mounting rail, how far a mounting rail extends from a body of a module, a depth of the mounting rail (e.g., in a direction perpendicular to the control surface and/or back surface), location of screw holes in the mounting rail, etc. A width of a module may conform to one or more width units. For example, a width unit may be regularized/standardized, with modules configured to have a width corresponding to an integer multiple of the width unit. The width may be related to height (e.g., a distance between the upper and lower edges of the module) such that a width unit is close or equal to half the height. Thus, a single-unit module will be a rectangle (e.g., narrower left to right than top to bottom), a 2-unit module may be approximately square, a 3-unit module will be a wider rectangle (e.g., wider left to right than top to bottom), and so on. Similarly, stands (e.g., for standalone use) and/or racks may be dimensioned according to this unit sizing to accept a module of a certain width or widths, or multiple modules up to a total width; for example, a rack having a 6-unit total width may house three 2-unit modules or any other combination of modules having combined widths up to and including six units.

A module may have screw holes at certain locations for mounting to a rack and/or stand. The positioning of the screw holes may correspond to the unit-size dimensioning of the modules. For example, a center of a screw hole may be positioned in a mounting rail a certain distance from a left or right edge of a module (and/or a certain distance from a top or bottom edge of the mounting rail). Thus, threaded holes may be placed in the rack at positions corresponding to the location of the screw holes in the modules. Screw holes of a module may also be used to mount the module to a stand and/or feet for standalone use. Feet may be attached to the module via a screw and screw hole, in some cases without regard to relative positions of the screw holes. A stand may correspond a particular unit width; for example, a single-unit stand may have threaded holes configured to accept screws inserted into the screw holes of a single-unit module, a 2-unit stand may have threaded holes configured to accept screws inserted into the screw holes of a 2-unit module, and so on.

A module may have one or more connectors for providing power and/or a data link to the module. A first connector may be disposed on a back-facing surface of one (or both) of the mounting rails of the module. The first connector may mate with a corresponding connector on the rack. The first connector may include spring-loaded contacts, also called spring-loaded pins, pogo pins, spring-loaded pogo pins, etc. A spring-loaded contact may mate with a corresponding receptacle by contact pressure alone; for example, without the friction associated with insertion of one contact into its corresponding contact in the mating connector. The mating force may be provided by screwing the module to the rack. A module may receive power and/or exchange data via the first connector. For example, a first pin may provide pins for a power ground and bus voltage (e.g., 5v, 12v, 24v, etc.), pins for CV and gate, a module detect pin or pins to detect whether a module is present, and/or or pins for digital communication such as serial data line (SDL) and serial clock line (SCL) for an Integer-Integrated Circuit (I²C or I³C) protocol, MIDI protocol, data− and a data+ connections for a universal serial bus (USB) protocol, or the like.

A second connector may include a standardized connector such as one of the USB configurations; for example, mini-USB, micro-USB, USB-C, etc. The second connector may be positioned along a top-and/or bottom-facing edge of the module; for example, where the mounting rail is recessed with respect to the control surface or back surface of the module. The module and/or rack may be configured such that the second connector may be accessed whether the module is mounted to the rack, mounted to a stand for standalone use, and/or unmounted/handheld. In some implementations, the module may be mounted to and/or removed from a rack/stand while a cable is inserted into the second connector. The second connector may, in various uses, provide power and/or a data link to the module. The module may be powered and/or controlled by a user device such as a personal computer, laptop tablet, mobile phone, etc., via cable connection to the second connector. The user device may additionally alternatively interface with the module wirelessly via, for example, Bluetooth, Bluetooth Low Energy, Wi-Fi, and/or other wireless protocol.

One or more modules may mount to a rack. A rack may include one or more rack panes. A rack pane may receive one or more modules arranged widthwise from left to right. A rack pane may include an upper rail configured to receive the upper mounting rail of a module, and a lower rail configured to receive the lower mounting rail of the module. The rack rails may be joined by rack arms at the left and right ends of the rack pane. A rack system may be made up of one or more rack panes. Rack panes may be joined via one or more joints. A rack may reside in a plane passing through the upper and lower rails of the rack pane. The joint(s) may include a clamp with detents (e.g., a rosette joint) to allow respective panes to be positioned at an angle with respect to each other (e.g., aligned or flat, at a right angle, an obtuse angle, etc.) and then held securely at that angle during use. The rack rails may have threaded holes positioned and configured to receive screws inserted through screw holes of the module(s). The screws removably affix the module(s) to the rack. The screws may also apply the mating force to engage the spring-loaded contacts of the first connector of a module.

The upper and/or lower rail of the rack may include connectors for mating with the corresponding above-described first connector of any module(s) mounted to the rack. Via this connector, the rack may supply power and/or provide a data connection to the module(s). A rack pane may additionally include one or more external connectors for connecting to a computing device such as a desktop or laptop computer, a personal device such as a smartphone or tablet, etc. The rack may act as a hub to provide data interconnectivity between the computing device and one or more audio equipment modules mounted in the rack. One or more of the external connectors may be used to provide electrical power to the rack and, by extension, modules mounted to the rack. In some cases, one or more of the external connectors may be a USB connector; for example, a USB-C receptacle. In some cases, the role of an external connectors may dynamically change from, for example, a power supply to a data link or vice-versa. The rack system may be powered and/or controlled by a computing device such as a personal computer, laptop tablet, mobile phone, etc., via cable connection. The rack system may additionally alternatively interface with the module wirelessly via, for example, Bluetooth, Bluetooth Low Energy (BLE), Wi-Fi, and/or other wireless protocol.

The rack system may include features for determining the identity and/or location of modules mounted thereto. The rack system may provide the identity and/or location information to the computing device via the external connector. A computing device with appropriate software may use the information to generate a virtual representation or “digital twin” of the rack system and modules. The digital twin may include a graphical user interface (e.g., on a display of the computing device) that looks like the rack system, with modules represented by visually similar images that are arranged in a manner corresponding to their physical arrangement in the rack system. The rack may determine location information for a module mounted within the rack. For example, each rack position may be associated with a small memory or controller component such as an electrically erasable programmable read-only memory (EEPROM) and/or a microcontroller unit (MCU) storing information about the location of the module connector within the rack system. The rack system may determine the location of a module based on the response of the module that is present in the targeted rack module position; for example, during a power-on sequence and/or periodic polling during runtime operation. A microcontroller, microprocessor, and/or other logic of the rack system may perform a power-on sequence that applies power to the EEPROM or MCU of each module connector in turn and reads the location of the module connector. In addition to the location identifier (LID), if the module connector is connected to a module, the rack system logic may additionally read a product identifier (PID) of the module. The module may also provide a unique identifier (UID) (e.g., a serial number, random number, pseudo-random number, etc. applied to the module) that may enable the rack system logic to distinguish between two of the same module mounted to the rack system. This may enable a connected computing system to control the modules separately. The rack system logic may also determine a power draw of a module. Thus, the power-on sequence may include measuring total power draw and determining whether it is within an acceptable range of the rack system and/or the power supply providing electrical power to the rack system. The rack system may output a status during and/or after the power-on sequence. The status may indicate normal operation and/or any errors detected as part of the power-on sequence. The status may include additional information such as a power budget remaining (e.g., indicating whether the rack system can handle the additional power draw of one or more additional modules).

The rack system may be configured with various input/output connections such as connectors for patch cables (e.g., to convey analog audio signals), control voltage (CV) and gate signals (e.g., for controlling analog synthesizers), MIDI signals, digital control signals (e.g., USB), etc. The rack system control surface may be configured with one or more various types of indicator and/or display such as a light-emitting diode (LED), mechanical and/or digital meter, liquid-crystal display (LCD), touchscreen, etc.

These features may be used alone or in combination with each other and/or other features of the present disclosure described below.

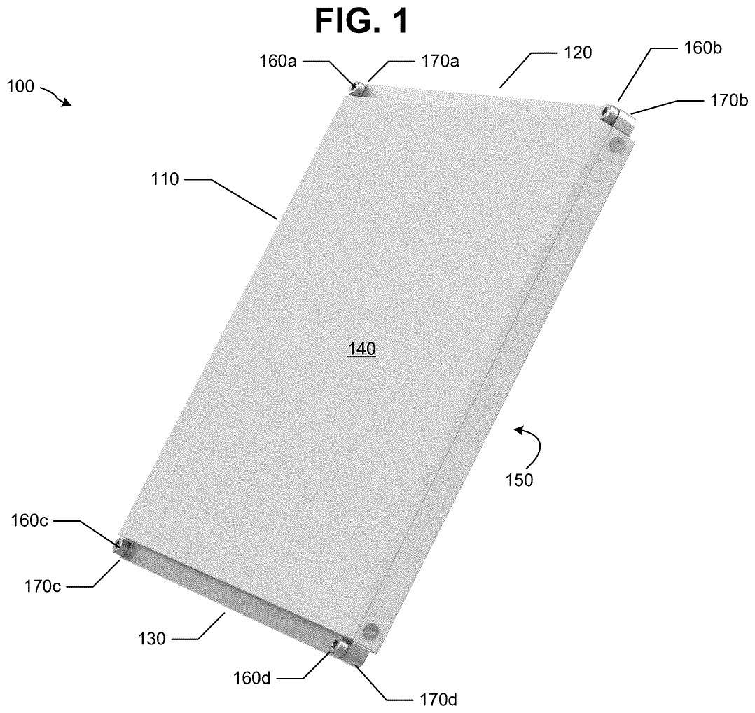

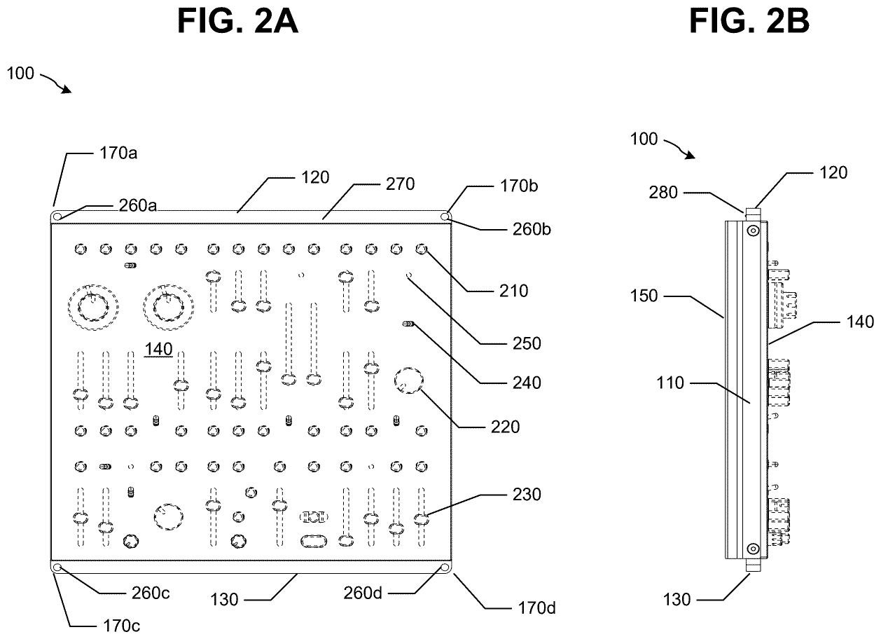

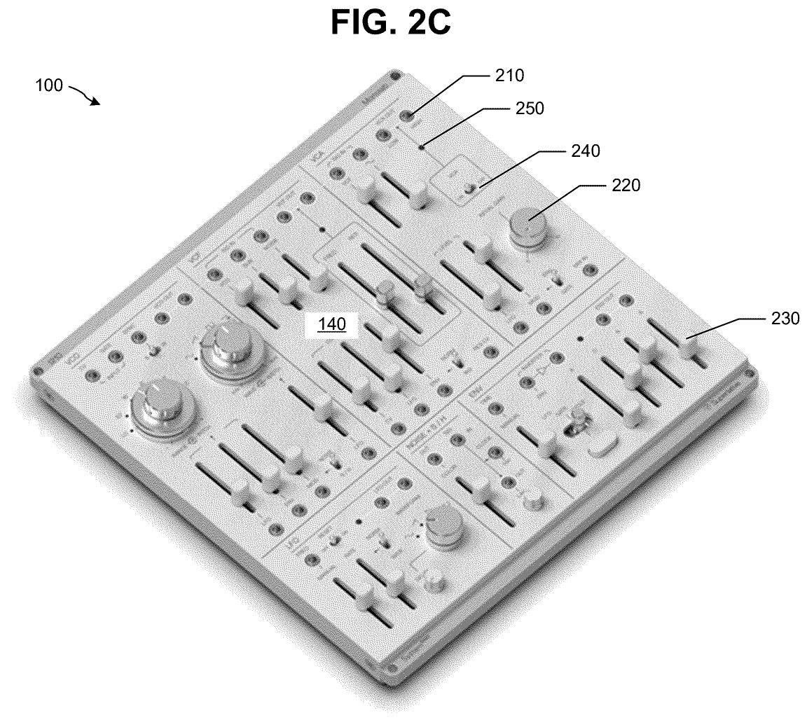

FIG. 1 illustrates an example audio equipment module 100, according to embodiments of the present disclosure. The module 100 may include a body 110, an upper mounting rail 120, and a lower mounting rail 130. The body 110 may include a control surface 140 (e.g., a front surface) and a back surface 150 (obscured in FIG. 1). The control surface 140 of the example module 100 shown in FIG. 1 is blank; that is, it does not include any control features. FIGS. 2A and 2B, described further below, show example control features.

Returning to FIG. 1, the upper mounting rail 120 and lower mounting rail 130 extend from the body 110 of the module 100. A front surface of the rails 120 and 130 (e.g., a surface parallel to the control surface 140 and facing a same direction) may be recessed with respect to the control surface 140. Thus, mounting screws 160a, 160b, 160c, 160d, etc. (collectively “mounting screw 160”) may be flush or recessed with respect to the control surface 140 when the module 100 is mounted to a rack and/or a stand/feet for standalone use. Such flush mounting may present a more aesthetic appearance.

Corners 170a, 170b, 170c, 170d, etc. (collectively “corners 170”) of the module 100 (e.g., at left and/or right ends of the rails 120 and/or 130) may be rounded for comfortable holding of the module 100 in the hand. A corner 170 may be rounded such that an outer edge of the rail 120 and/or 130 has a radius parallel to a plane corresponding to the control surface 140. The radius may be from one to several millimeters; for example, 1 mm, 2.5 mm, 5 mm, 7.5 mm, 10 mm, etc. The radius may be similar to that of the head of the mounting screw(s) 160 such that a radiused edge of the mounting screw(s) 160 aligns with a radiused edge of the corner(s) 170.

FIG. 2A illustrates a front view of an example module 100 showing a control surface 140 and rails 120 and 130, according to embodiments of the present disclosure. The rails 120 and/or 130 may include screw holes 260a, 260b, 260c, 260d, etc. (collectively “screw holes 260”) configured to accept screws for mating to a rack or stand. From the front view, the radius of the corners 170 is apparent. The control surface 140 may have numerous control features, indicators, and/or connectors disposed on in. For example, the module 100 may include one or more connectors 210 (e.g., for patch cables and/or other cable connections), one or more knobs 220, one or more sliders 230, one or more switches 240, one or more LED indicators 250, etc.

FIG. 2B illustrates a side view of the example module 100, according to embodiments of the present disclosure. FIG. 2B illustrates how some of the control features may protrude from the control surface 140; for example, to allow for easy manipulation. FIG. 2B further illustrates how surfaces of the rails 120 and 130 may be recessed with respect to the adjacent surface of the body 110. For example, a front-facing surface 270 of the upper mounting rail 120 may be recessed with respect to the control surface 140 as previously described, and a back-facing surface 280 of the upper mounting rail 120 may be recessed with respect to the back surface 150.

FIG. 2C illustrates a side view of the example module 100, according to embodiments of the present disclosure. FIG. 2C illustrates various control features of the control surface 140 in more detail including the connector 210, knob 220, slider 230, switch 240, and LED indicator 250.

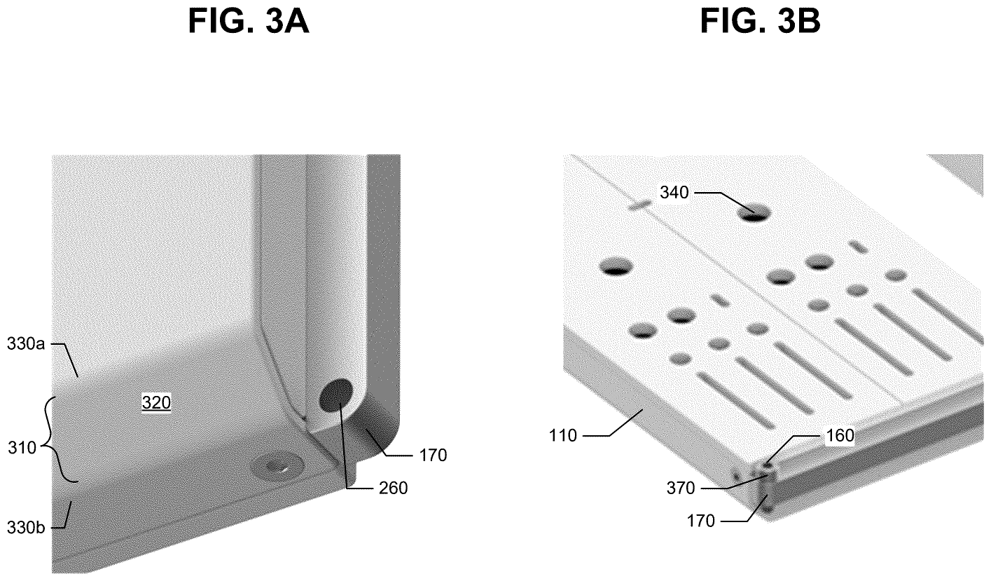

FIG. 3A illustrates a first view of an example module 100 detailing a corner 170 and screw hole 260, according to embodiments of the present disclosure. FIG. 3A also shows a lower lateral edge 310 of the body 110. The lower lateral edge 310 may be configured with a chamfer 320 and/or rounded edges 330a and/or 330b (collectively “rounded edges 330”). The chamfer 320 and/or rounded edges 330 may make gripping the module with the hands more comfortable and ergonomic.

FIG. 3B illustrates a second view of an example module 100 detailing a corner 170 and screw hole 260 with a screw 160, according to embodiments of the present disclosure. As shown in FIG. 3B, the radius of the corner 170 may be similar to that of the head 370 of the mounting screw(s) 160 such that a radiused edge of the head 370 aligns with a radiused edge of the corner(s) 170 to further dull/soften the corner to improve ergonomics. The control surface 140 is shown with openings 340 through which control features may pass or protrude from, for example, a circuit board within the body 110.

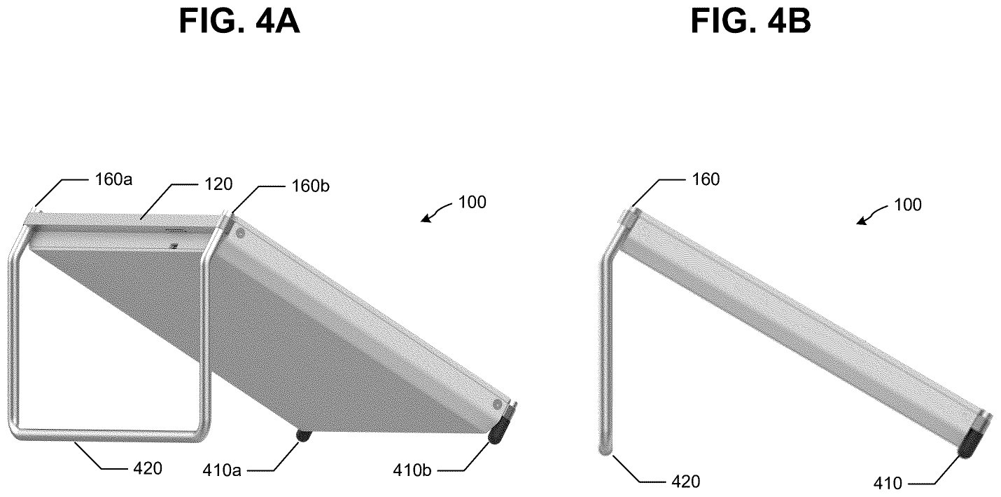

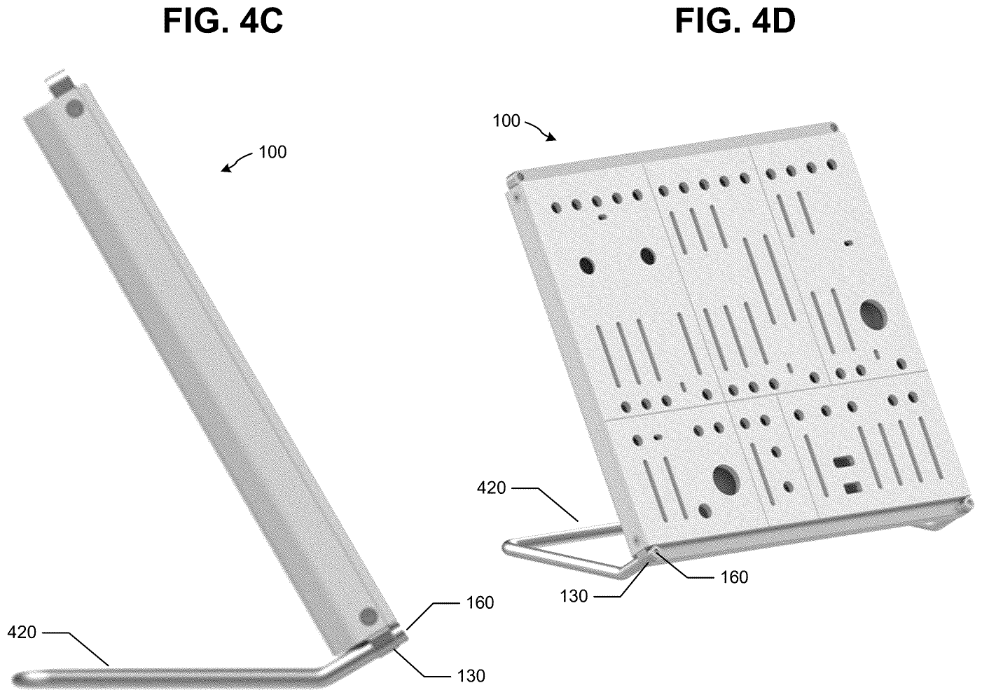

FIGS. 4A and 4B illustrate different views of a module 100 in a first example standalone configuration, according to embodiments of the present disclosure. In the first example standalone configuration, the module 100 may have feet 410a and 410b (collectively “feet 410”) mounted to the screw holes 260a and 260b of the lower mounting rail 130, and a u-shaped (e.g., bent wire) stand 420 mounted to the screw holes 260c and 260d of the upper mounting rail 120. The stand 420 may be fashioned from a pipe with threaded holes at each end for receiving the mounting screws 160a and 160b.

The stand 420 may be angled and/or have a length configured to present the control surface 140 at different angles. For example, the configuration shown in FIGS. 4A and 4B, in which the stand 420 is mounted to the upper mounting rail 120, may present the control surface 140 at an approximately 30-degree angle with respect to a desktop, tabletop, or other surface on which the module 100 is placed. In contrast, the configuration shown in FIGS. 4C and 4D, in which the stand 420 is mounted to the lower mounting rail 130, may present the control surface 140 at an approximately 60-degree angle with respect to the surface on which the module 100 is placed. In yet another configuration (not pictured), the module 100 may be fitted with four feet 410 (or nothing mounted to the screw holes 260 at all) and may lay flat on the surface.

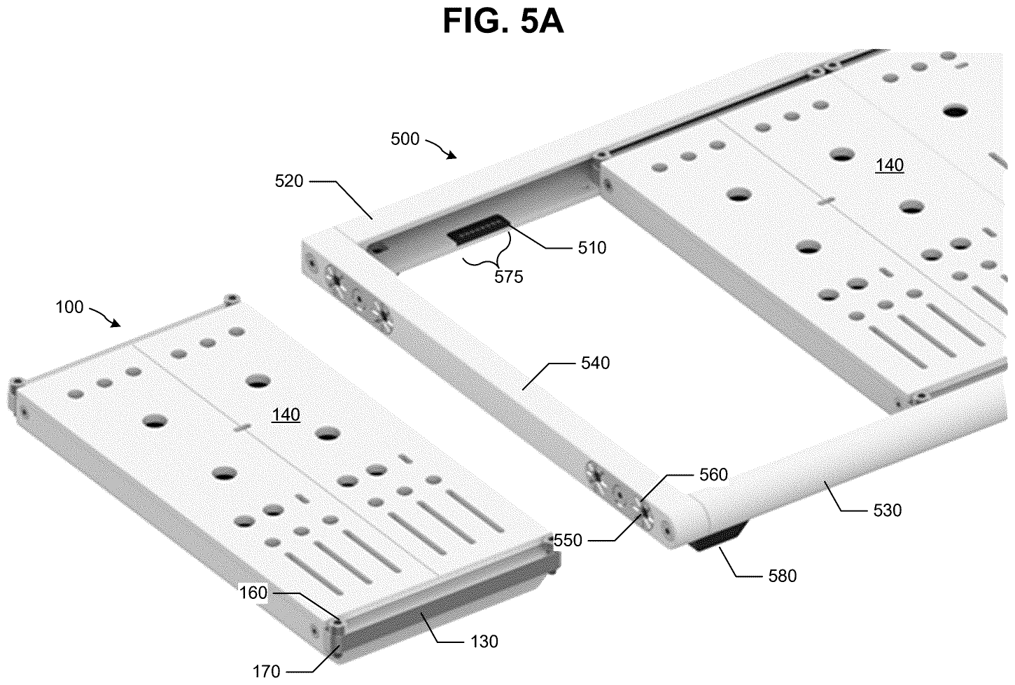

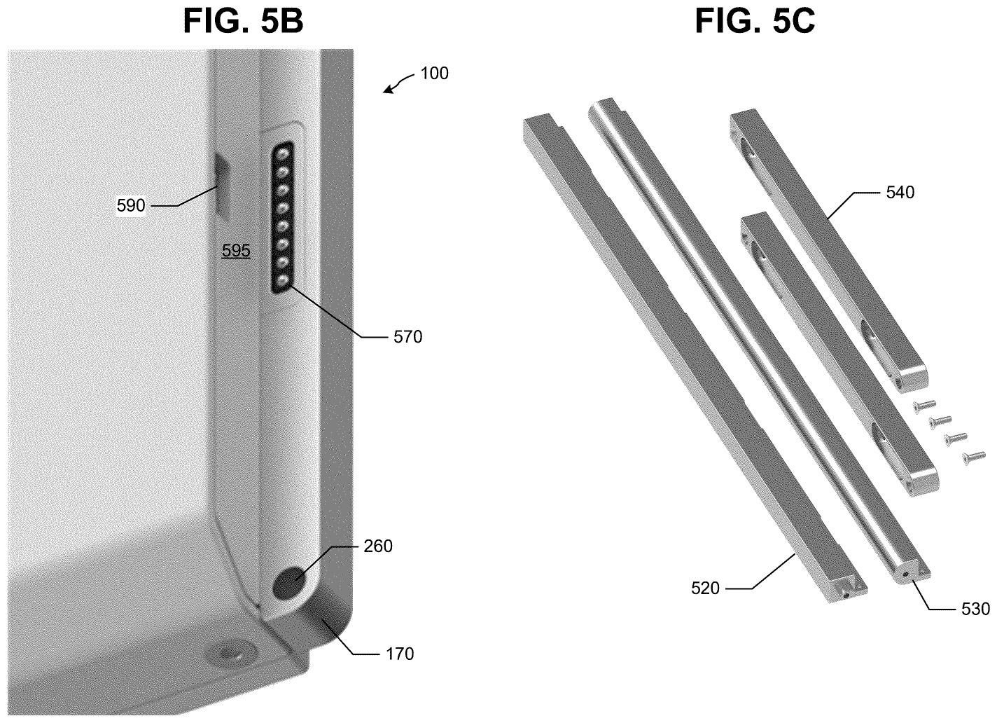

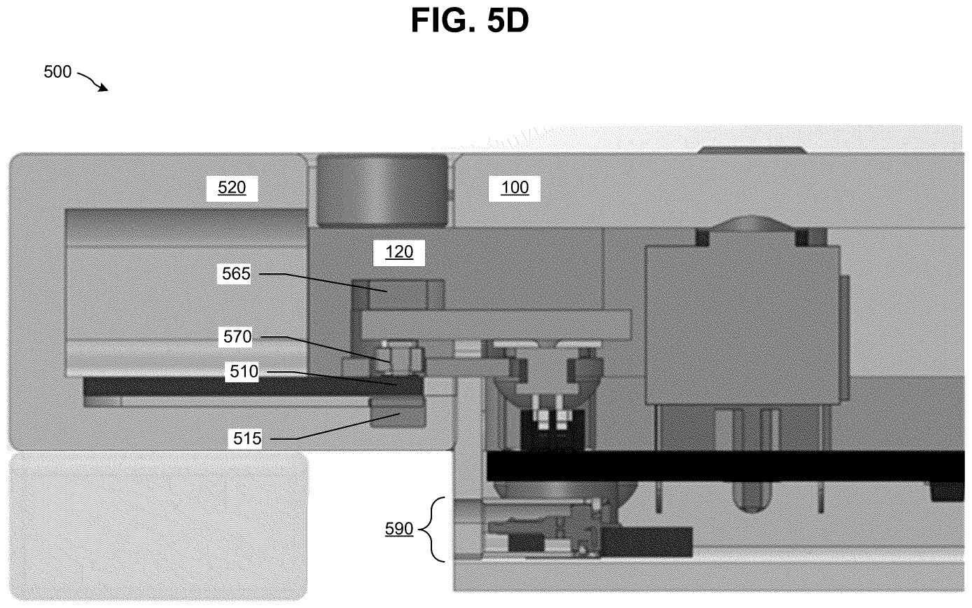

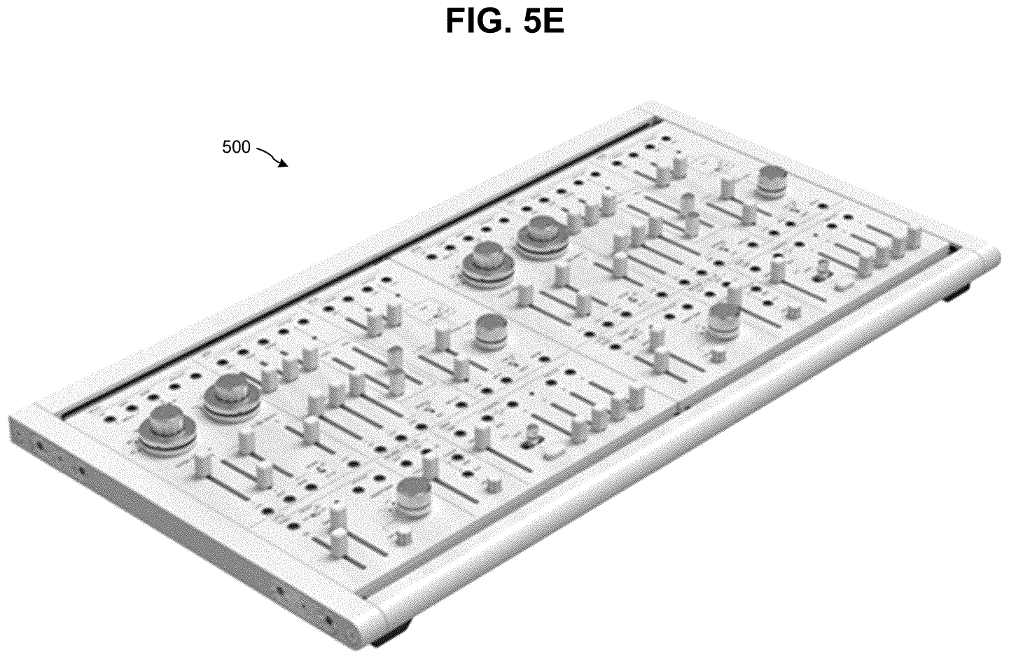

FIG. 5A illustrates an example rack 500 and audio equipment module 100, according to embodiments of the present disclosure. The rack 500 includes an upper rail 520 and a lower rail 530. The upper and lower rack rails 520 and 530 are configured to receive the upper and lower mounting rails 120 and 130, respectively, of the module 100. The upper and/or lower rack rails 520 and 530 may include a module connector 510. The upper rail 520 may be shallower than the lower rail 530 so that when a module 100 is mounted and installed, a cable connector port of the module 100 (e.g., the second connector 590 shown in FIG. 5B) may have enough clearance for cable access even when the module connector 510 is in use. The module connector 510 may be associated with an EEPROM, MCU, and/or other logic for performing identity and/or location information of a module 100 connected to the module connector 510. The upper and lower rack rails 520 may be connected on the lateral sides by a rack arm 540. The rack arm 540 may be joined to the upper and lower rack rails 520 and 530 via one or more screws. One or more of the upper and lower rack rails 520 and 530 and/or the rack arms 540 may include a foot or pad 580 for placing on a surface (e.g., desktop or tabletop). In some implementations, the rack arm 540 may additionally or alternatively include a threaded hole 550 and rosette 560 (e.g., defining radial detents) for mating with another rack pane via a joint (not shown). Examples of a rack 500 having multiple panes is described in later figures. The threaded hole and rosette mechanism may be removable, so that a magnet may be embedded behind the mechanical mating surface, or made of magnetized or ferrous material itself such as steel, etc.

FIG. 5B illustrates the example audio equipment module 100 showing a first connector 570 and second connector 590, according to embodiments of the present disclosure. The second connector 590 may be a USB connector or the like for providing electrical power and/or a data link to the module 100 when used in a standalone or handheld mode. The second connector 590 may be positioned along an upper-facing surface 595 of the module and distanced from the upper mounting rail 120 to allow insertion of a cable when the module 100 is mounted in the rack 500.

The first connector 570 may include a plurality of spring-loaded contacts 575. When the module 100 is mounted to the rack 500 and the mounting screws 160 are engaged, the first connector 570 may mate with the module connector 510 of the rack 500. The spring-loaded contacts 575 may be configured to engage with corresponding mating surface of the module connector 510. Engagement may be by contact pressure alone (e.g., without a fractioned insertion into a receptacle). Such spring-loaded contacts 575 may be low-profile and thus resistant to damage from bending and/or impacts. In addition, the spring-loaded contacts 575 may have a rounded profile unlikely to poke or abrade the skin. The connectors 510 and 570 may be positioned to provide the correct contact pressure when the mating surfaces of the mounting rail 120 and rack rail 520 are engaged. In other words, the mechanical interference between the robust mounting rail 120 and rack rail 520 may prevent overtightening and/or over-pressuring the spring-loaded contacts, yet provide a sufficient contact pressure to form reliable electrical connections between each spring-loaded contact 575 and its corresponding receptacle in the module connector 510. In some implementations, the module connector 510 and/or the first connector may include a magnet and/or magnetic ferrous material. The magnetic features may promote alignment of the respective connectors with regard to each other during insertion and fastening (e.g., with the screws 160) of a module 100 to the rack 500.

An electrical contact such as the spring-loaded contacts 575 may be referred to as a “pin” and may correspond to a particular role or signal. For example, two or more pins may provide a voltage bus and ground, two or more pins may provide a digital signal connection (e.g., via I2C, USB, etc.), two or more pins may provide control signals for audio equipment (e.g., CV and gate and/or a variable resistance between the pins), and the like. Among the signals and information transmitted via the first connector 570 may be the PID and/or UID of the module 100. The module connector 510 may include a module detect pin that the rack 500 may use to determine whether or not a module 100 is currently installed in that position. During operation, the rack 500 may occasionally and/or periodically poll the module detect pin of each module connector 510 to determine whether a module 100 has been as added/removed. The rack 500 can send a notification to a computing device connected to the rack and/or illuminate an indicator 695 upon detecting the configuration change. This may allow the computing device to update its virtual representation of the rack system 500 and modules 100 to match the current configuration. FIG. 5C illustrates the example rack 500 with the upper and lower rack rails 520 and 530 and rack arms 540 disassembled, according to embodiments of the present disclosure. The rack 500 may be broken down for ease of transport and/or shipping.

FIG. 5D illustrates a detailed cross section of the example rack 500 and audio equipment module 100 showing additional features of the module connector 510 and first connector 570, according to embodiments of the present disclosure. In some implementations, the first connector 570 and the module connector 510 may include features for aligning the two during mounting of a module 100 in the rack 500. For example, the first connector 570 and/or the module connector 510 may include a magnet 565 and/or 515. In some implementations, the magnet 565 or 515 may be replaced with ferrous or other suitable material that may be attracted by the remaining magnet 565 or 515.

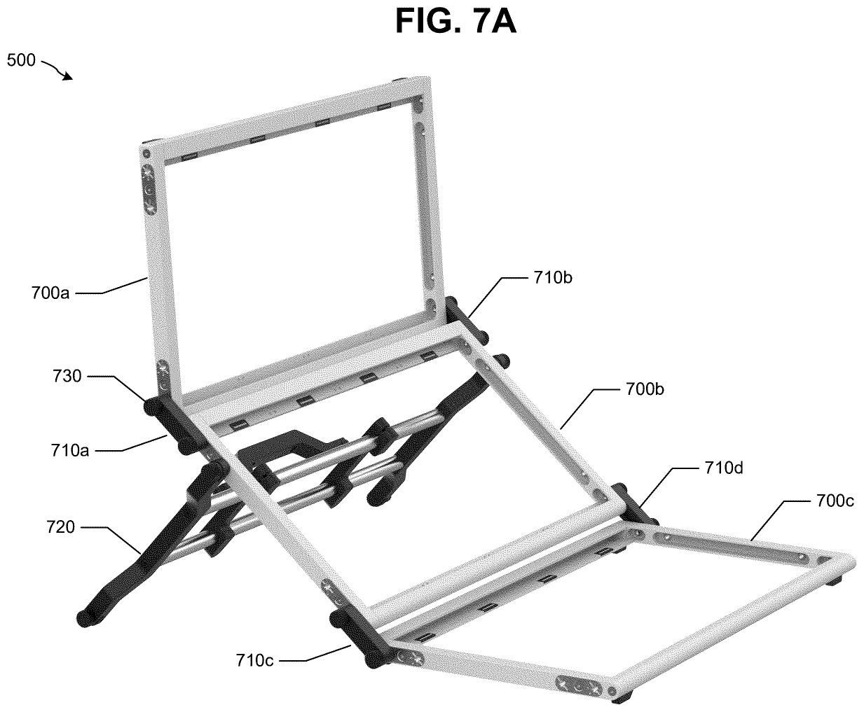

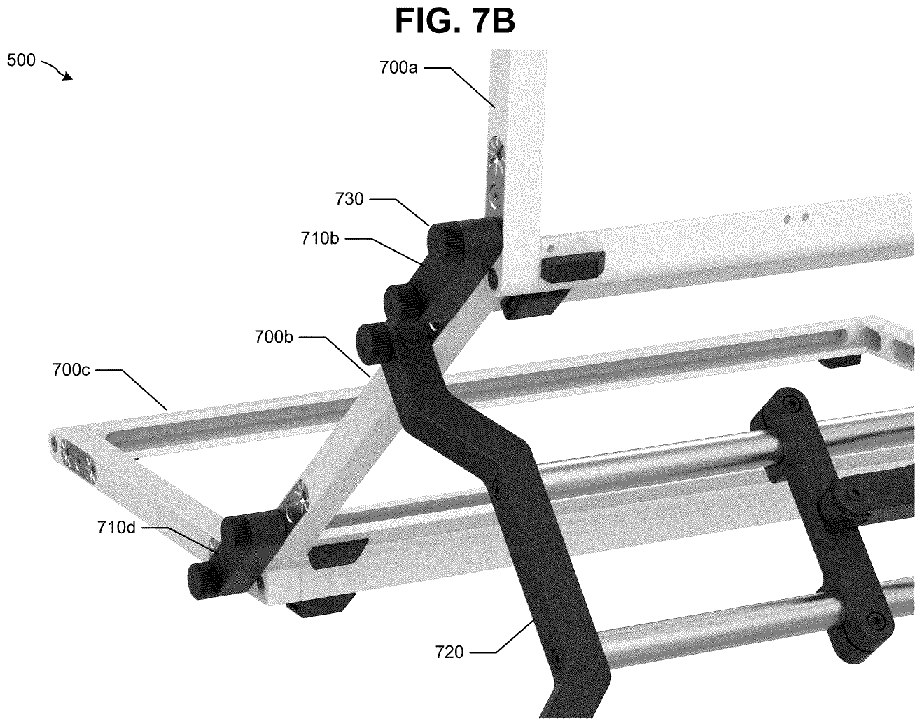

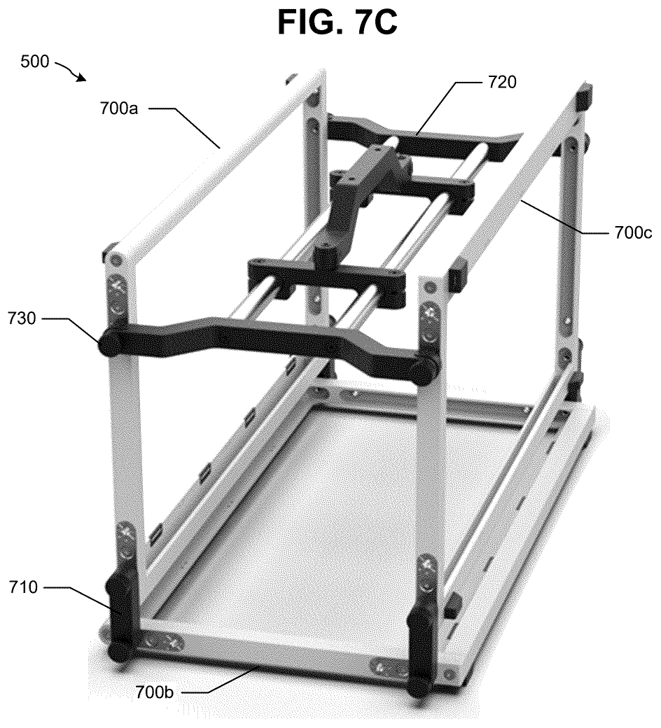

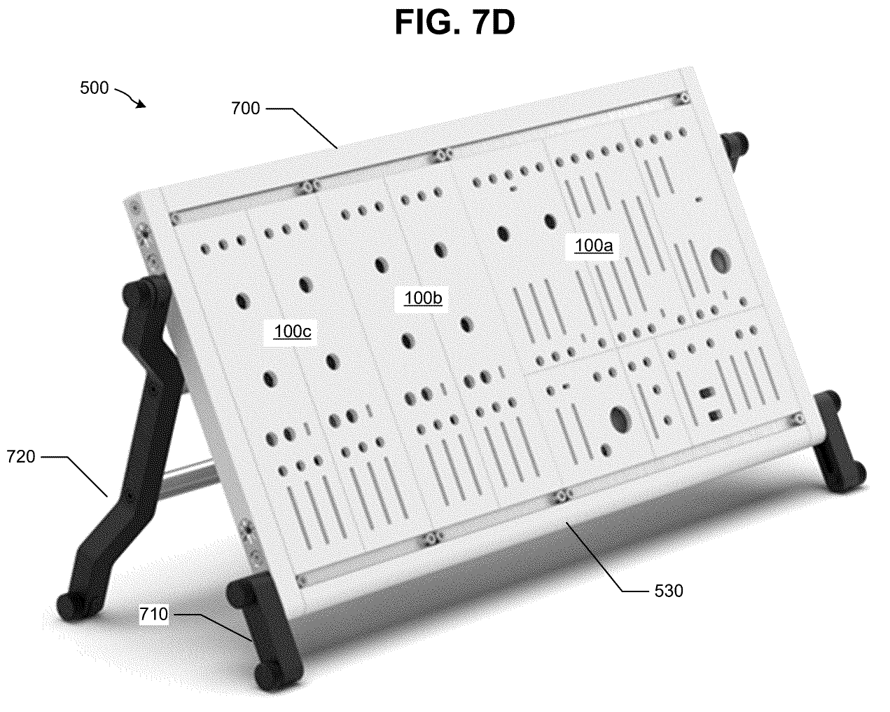

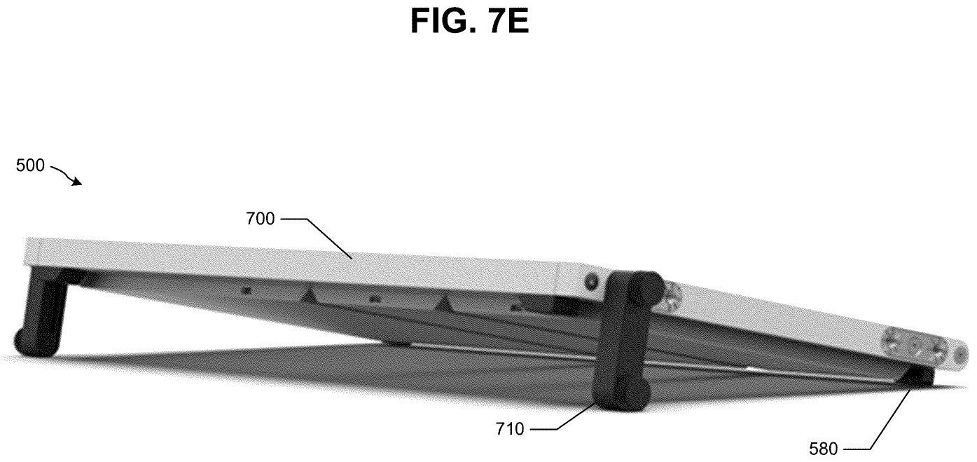

FIG. 5E is an isometric view of the example rack 500 and audio equipment modules 100 showing the control features of modules 100 in more detail, according to embodiments of the present disclosure. As shown in FIG. 7C and described below, a multi-pane rack system may be configured for storage/transportation by arranging panes of the rack system 500 with the control features facing inwards to protect from damage from impacts, etc.

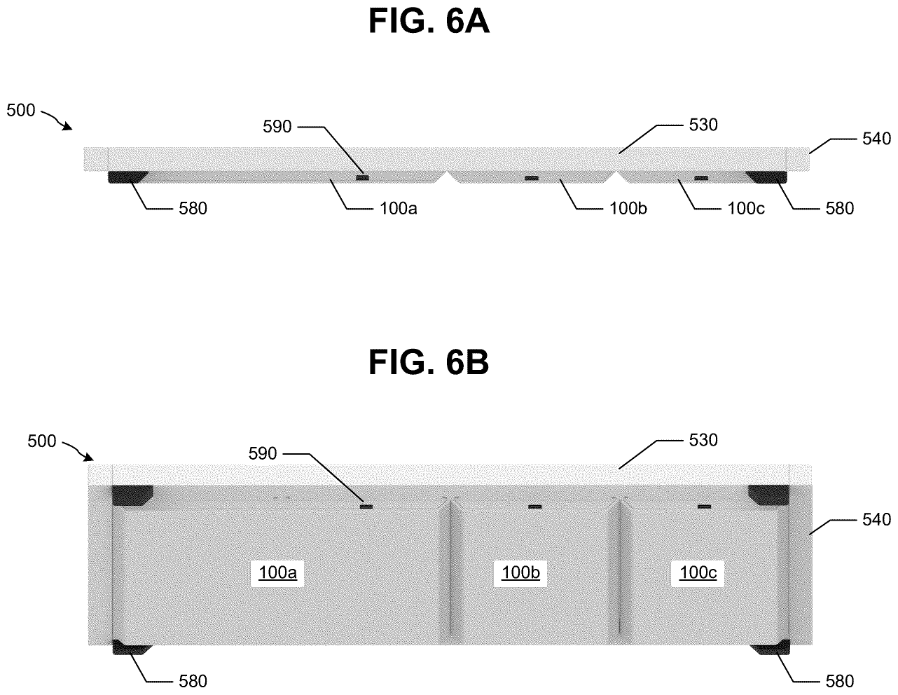

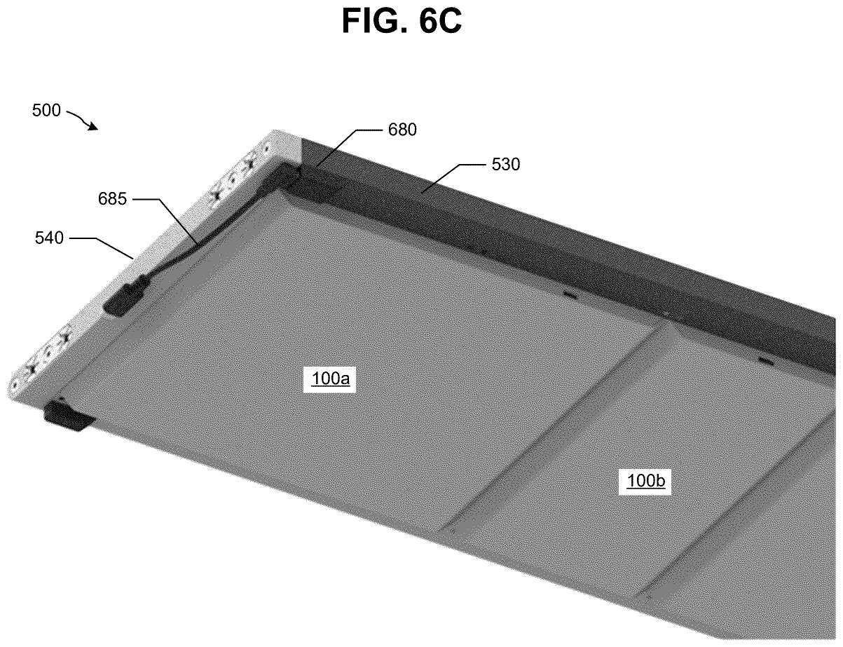

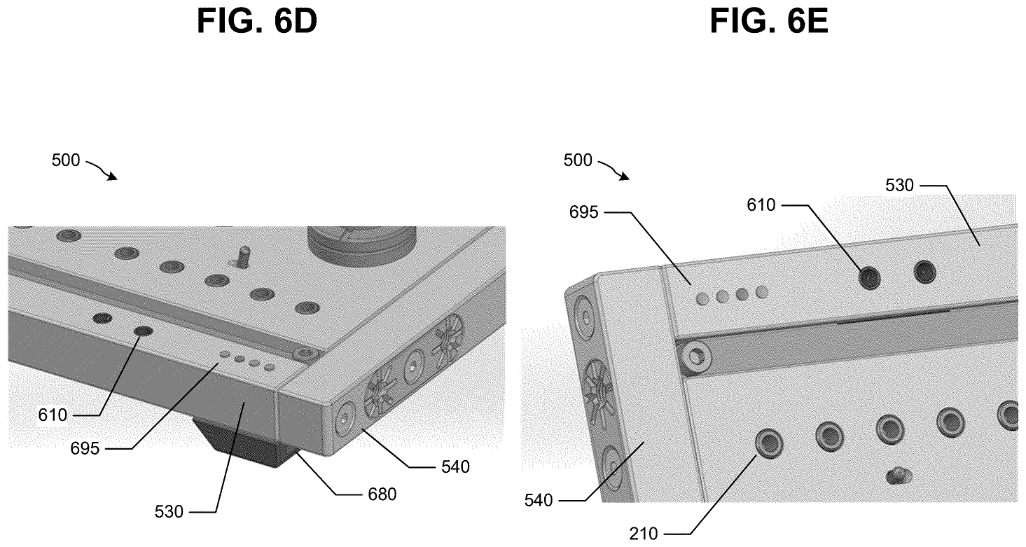

FIGS. 6A and 6B illustrate different views of an example rack 500 with modules 100 installed, according to embodiments of the present disclosure. FIG. 6A shows the rack 500 from the lower side. The rack 500 has three modules 100a, 100b, and 100c. The modules 100 correspond to standard widths. For example, the first module 100a has a 2-unit width and the second and third modules 100b and 100c have a single-unit width. The second connector 590 is visible in each module 100 below the lower rack rail 530. FIG. 6B shows the rack 500 angled slightly upward to reveal the back surface 150 of the modules 100. The view in FIG. 6B shows the different aspect ratios of the modules 100; for example, approximately 1:1 for the first module 100a, and 1:2 for the second and third modules 100b and 100c (e.g., longer between mounting rails 120 and 130 than wide).

FIG. 6C illustrates a third view of an example rack 500 with modules 100 installed and an external digital connection, according to embodiments of the present disclosure. The external digital connection may include one or more external connectors 680a, 680b, etc. (collectively “external connectors 680”) (e.g., a USB-C receptacle) integrated into and/or replacing a foot or pad of the rack 500. In some implementations, the external connector 680 may be located in a different portion of the rack 500; for example, in a rack arm 540 and/or rack rail 520 or 530. A computing device may connect to the rack 500 via a cable 685 such as a USB-C cable.

FIG. 6D and 6E illustrate views of an example rack 500 further detailing various indicators and connectors, according to embodiments of the present disclosure. In some implementations, the upper rack rail 520 may include one or more indicators 695 and/or connectors 610. The connector(s) 610 may be, for example, 3.5 mm audio connectors that may be used for patch cables, headphones, auxiliary line-in, CV and gate, etc. The indicator(s) 695 may include one or more LEDs that may illuminate (e.g., under the control of a rack controller 800 as described below) to indicate information to the user regarding, for example, whether a module 100 is installed at a particular position, whether that module 100 is functioning properly (e.g., within normal operating parameters related to power consumption, etc.), whether the rack system 500 is experiencing an overpower event, whether the rack system 500 has detected the addition and/or removal of a module 100, etc. In some implementations, the rack system 500 may include multiple indicators 695 such that an indicator corresponds to a respective module position in the rack 500. In this manner, the rack system 500 can indicate a status of the particular module 100 to the user. FIG. D also shows another view of the external connector 680. In some implementations, the indicator(s) 695 and/or connectors 610 may be in a different location on the upper rack rail 520 and/or on a different component of the rack system 500 such as the rack arm 540, lower rack rail 530, etc.

FIG. 7A illustrates a first view an example rack system 500 open for use, according to embodiments of the present disclosure. The rack system 500 shown in FIGS. 7A through 7C includes three rack panes 700a, 700b, 700c (collectively “rack panes 700”) joined by joints 710a, 710b, 710c, and 710d (collectively “joints 710”). A lateral rack arm 540 may include a threaded hole 550 and rosette 560 (e.g., defining radial detents) for mating with another rack pane 700 via a joint 710. The joints 710 may include one or more protrusions configured to extend at least partially into the detents of the rosette 560 and, when a thumb screw 730 is inserted through a whole of the joint 710, into the threaded hole 550, and tightened. Thus, tightening the thumb screw 730 may resist or prevent a rotational movement of the joint 710 with respect to the lateral rack arm 540 (e.g., about an axis of the thumb screw 730).

The rack panes 700 may have dimensions that correspond to the standardized dimensions of the modules 100. For example, a rack pane 700 may form an open rectangle having an internal height (e.g., measured in a direction parallel to a length of the lateral rack arms 540) corresponding to the height of the modules 100, and an internal width (e.g., measured in a direction parallel to the upper rail 520 and the lower rail 530) corresponding to an integer multiple of a standardized module width (e.g., to fit 1, 2, 3, etc. modules). The upper and lower rails may include threaded screw holes into which the mounting screws 160 may be fastened. The rack system 500 further includes a handle/stand assembly 720. One end of the handle/stand assembly 720 is attached too one of the rack arms 540 while the other end rests on the surface of the table/desk.

FIG. 7B illustrates a second view of the example rack system 500 open for use, according to embodiments of the present disclosure. The joints 710 and/or handle/stand assembly 720 may include one or more thumb screws 730 for affixing the joints 710 and/or the handle/stand assembly 720 to the rack system 500. The thumb screws 730 may compress the joints 710 and/or the handle/stand assembly 720 against the rosettes 560 to lock the rack panes 700 at the desired angle with respect to each other and/or the surface on which the rack system 500 is placed. A magnet may be embedded and centered behind this joint 710 to promote immediate and correct alignment on the correspondingly magnetized mating surface of the threaded hole 550 and rosette 560 and to hold and support the correct position while the user fastens the thumb screw 730 to lock the rack panes 700 in the desired positions.

FIG. 7C illustrates the example rack system folded closed for transit or storage, according to embodiments of the present disclosure. The first rack pane 700a and third rack pane 700c may fold together until they are substantially parallel or past parallel. The handle/stand assembly 720 that propped the rack system 500 up for use as shown in FIGS. 7A and 7B may be relocated and reattached to the rack system 500 in FIG. 7C to hold the rack panes 700 closed (e.g., to form an enclosure that protects the control surfaces 140 and the control features disposed thereon from dirt, impacts, and/or other damage from the outside world). Transition from the use mode of FIGS. 7A and 7B to the transit/storage mode of FIG. 7C may be aided by the thumb screws 730, with which the rack system 500 may be easily adjusted into the desired configuration. In the transit/storage mode of FIG. 7C, the end of the handle/stand assembly 720 previously resting on the surface of the table/desk is attached to a second rack pane 700 of the rack system 500. The handle/stand assembly 720 thus holds a first rack pane and second rack pane 700 together securely in the configuration shown in FIG. 7C.

FIG. 7D illustrates an example of a rack pane 700 mounted using a handle/stand assembly 720 of the rack system 500, according to embodiments of the present disclosure. The handle/stand assembly 720 may prop the rack system 500 at the desired angle of use using the rosettes 560 to lock the rack panes 700 at the desired angle. In some cases, a joint 710 of the rack system may serve as a foot for the lower edge of the rack system 500 to protect the finish of the lower rack rail 530 and/or to set the rack pane 700 at the desired height.

FIG. 7E illustrates an example of a rack pane 700 mounted using a joint 710 of the rack system 500, according to embodiments of the present disclosure. The joint 710 may be used to prop the rack pane 700 up at a shallower angle with the respect to the desktop/tabletop surface, while the lower end of the rack pane 700 rests on its foot or pad 580.

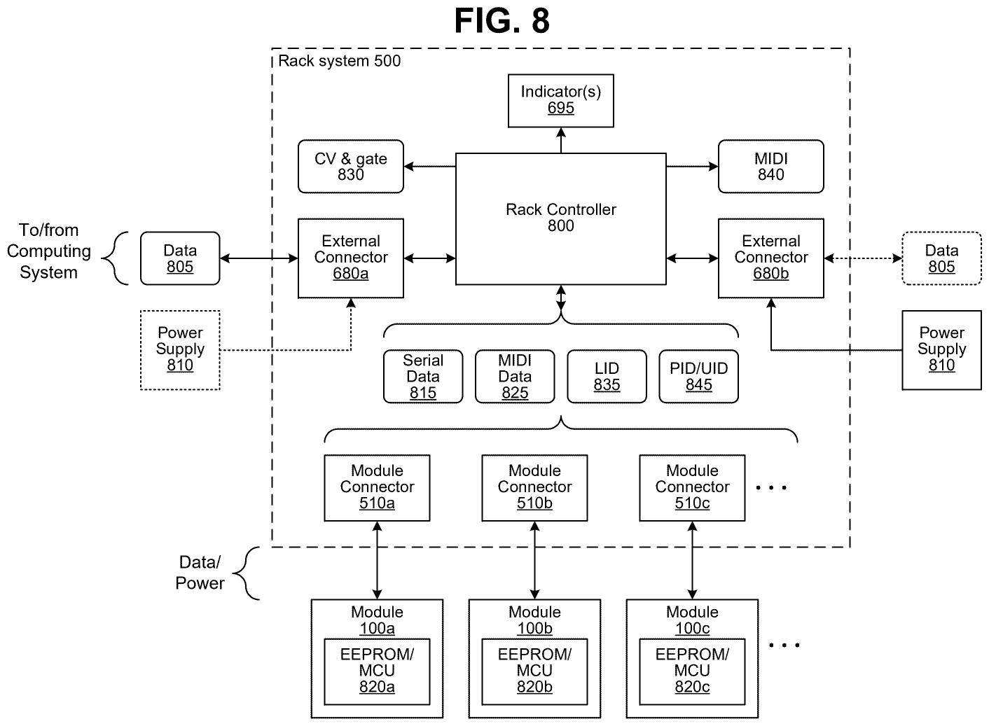

FIG. 8 is a conceptual diagram illustrating components of the rack system 500, according to embodiments of the present disclosure. The rack system 500 may have a controller 800. The controller 800 may include logic, memory, and/or software configured to perform the operations described herein including the power-on sequence and conveying data between an external computing system and the modules 100. The controller 800 may include, for example, one or more processors such as a microcontroller, microprocessor, system on chip (SoC), application-specific integrated circuit (ASIC), etc. The rack system 500 may include one or more external connectors 680a, 680b, etc. (collectively “external connectors 680”). The external connectors 680 may receive electrical power from a power supply 810 and/or convey data 805 (e.g., serial data, MIDI data, etc.) between the rack system 500 and a computing system. In some implementations, the rack controller 800 may include a separate MIDI connection 840. The MIDI connection 840 may correspond to, for example, corresponding MIDI receptacle on the rack system 500; for example, on one of the rack rails 520 or 530 and/or rack arms 540. In some configurations, the rack system 500 may receive power and data 805 from one of the external connectors 680. In some configurations, the rack system 500 may receive power and data 805 from separate external connectors 680. In some configurations, the rack system 500 can switch which external connector 680 it receives power and/or data 805 from while in operation.

The rack system 500 may include a plurality of module connectors 510a, 510b, 510c, etc. (collectively “module connectors 510”). A module connector 510 may connect to a module 100 mounted to the rack system 500 (e.g., via a first connector 570). The module connector 510 may convey power to the module 100 and data to and from the module 100. The module connector 510 may convey serial data 815 (e.g., via a USB protocol) and/or MIDI data 825 to and/or from the module 100. In various implementations, the module connector 510 may convey analog signals (e.g., CV and gate). In some implementations, the rack controller 800 may include a separate CV and gate connection 830. The CV and gate connection 830 may correspond to, for example, corresponding jack and/or receptacle on the rack system 500; for example, on one of the rack rails 520 or 530 and/or rack arms 540. The module connector 510 may also receive PID and/or UID data 845 from the module 100. In some implementations, the PID and/or UID may be assigned to a module and stored in a non-volatile read-only memory (ROM). The rack controller 800 may read the contents of the ROM during the power-on sequence. During the power-on sequence, the rack controller 800 may give a module 100 a UID. The rack controller 800 may use the UID to, for example, disambiguate to of the same type of module 100 mounted to the rack and/or determine their respective positions. During operation, the rack controller 800 may use the PID/UID data 845 determined during the power-on sequence to generate the LID data 835 used to identify modules 100 according to location within the rack system 500.

A module 100 may be associated with an EEPROM and/or MCU 820. The EEPROM/MCU 820 may correspond to I²C functions. A module 100 may be manufactured with the EEPROM/MCU 820, which may be programmed at the factory with, for example, the PID and/or UID data 845. The rack controller 800 may use the PID/UID data 845 to determine the LID data 835 and location of a module 100 in the rack system 500 (e.g., for building a virtual representation of the rack system 500 and modules 100 in a computing system). The EEPROM/MCU 820 may also convey data to and from the module 100 via the module connector 510.

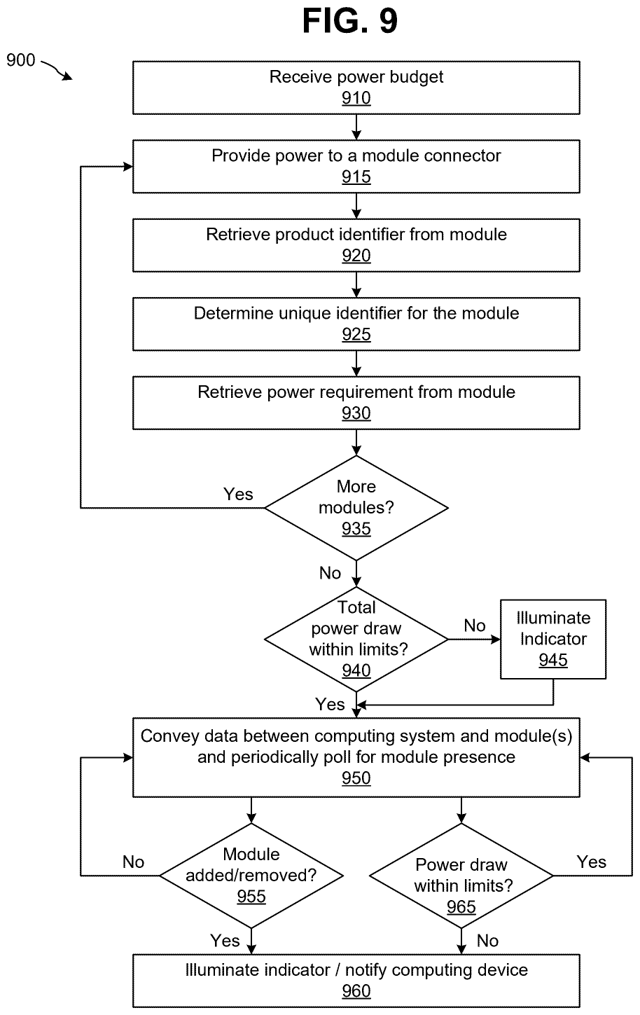

The rack controller 800 may perform a power-on sequence to identify modules 100 mounted to the rack system 500. The power-on sequence may include applying power to each EEPROM/MCU 820 in turn. In some implementations, the rack controller 800 may determine the power draw of individual modules 100 and/or the total power draw of all modules 100 mounted to the rack system 500 during the power-on sequence. If the rack controller 800 determines that the total power draw of the mounted modules 100 exceeds the limits of the power supply 810, external connector 680, and/or other circuitry of the rack system 500, the rack controller 800 may illuminate an indicator 695 (e.g., a blinking red LED) to notify a user that the rack system 500 may not operate optimally. The rack controller 800 may, however, provide or attempt to provide power to as many modules 100 as possible. In some implementations, a module connector 510 may be associated with a power switch (not shown), with overcurrent protection (e.g., set to a module's nominal power draw plus a margin of, for example 20%). If a power switch detects a power draw greater than the overcurrent protection, the power switch may disconnect power from the offending module and/or notify the rack controller 800. In response, the rack controller 800 may illuminate the indicator 695. In some cases, the rack controller 800 may determine that more power can be provided to one or more of the mounted modules 100 if the power supply voltage is raised. For example, the rack system 500 may be configured to operate at a nominal 5V; however, many, if not all, of the modules 100 may include switching power supplies that enable them to run on voltages from 4V to 12V and potentially higher. Running at a higher voltage may allow a module 100 to consume more total power for a given current limit, for certain module applications or functions. FIG. 9, described below, illustrates example operations of a power-on sequence method.

FIG. 9 is a flowchart illustrating example operations 900 of a power-on sequence of the rack system 500, according to embodiments of the present disclosure. The rack controller 800 may power on upon receiving power from an external power supply. The rack controller 800 may commence the power-on sequence. The operations 900 may include receiving (910) a power budget. The power budget may correspond to, for example, the capacity of a power supply powering the rack system 500 and/or a cable conveying electrical power from the power supply to the rack system 500. For example, a USB-C cable/connector may include a configuration channel (CC) over which the rack system 500 and power supply may convey and/or negotiate the voltage and/or current that may be provided to the rack system 500. The operations 900 may include providing (915) power to a first module connector. The rack controller 800 may cause power (e.g., an electric voltage and/or current) to be applied to each module connector 510 in turn; thus, at each iteration, the rack controller 800 may provide power to the next known module position. In some cases, the rack controller 800 may determine whether a module 100 is mounted in that module position (e.g., connected to the corresponding module connector 510). In some implementations, the rack controller 800 may initialize each rack position in an intermediate state where only a module detect pin is used to power the EEPROM/MCU 820. The rack controller 800 may, using the module detect pin, read and/or assess a power requirement of the module 100. The rack controller 800 may, however, read the power requirements for the modules 100 that are installed and determine the total power requirement of the installed modules 100 (e.g., at a step 940) prior to providing full power to the modules 100.

The operations 900 may include retrieving (920) a PID from the module. A module 100 may have a PID assigned at the factory and stored in a non-volatile ROM. The operations may include determining (925) a UID for the module. In some cases, the rack controller 800 may assign a UID to the EEPROM/MCU 820 of the module 100. The rack controller 800 may use the LID and retrieved PID to assign the UID to the module 100. In some cases, the rack controller 800 may read a previously assigned UID from the EEPROM/MCU 820 of the module 100. The EEPROM/MCU 820 of the module 100 may also store a power requirement form the module 100. This may enable the rack controller 800 to determine appropriate operating characteristics of the module 100 such that it may determine if/when the module 100 enters an overcurrent condition and/or exhibits some other malfunction. Thus, the operations 900 may include retrieving (930) power requirement information for the module. The operations 900 may determine (935) whether there are more modules to power on. If so (“Yes” at 935), the operations may return to the step 915 and repeat the steps 915 to 935. If not (“No” at 935), the rack system 500 may proceed to a step 940. The operations 900 may include determining (940) whether a sum of the power draw of the module or modules initiated thus far have a total power draw that exceeds a threshold limit of the rack system 500. If the total power draw exceeds the threshold (“No” at 940), the operations may include illuminating (945) an indicator of the rack system 500—for example, with a blinking red LED—to notify the user of a potential malfunction. The rack system 500 may continue operating, however, to the extent that it is able. For example, the rack controller 800 may attempt to provide power to as many modules as it can without exceeding the capacity of the power supply, connectors, rack system 500 circuitry, etc. Thus, the operations 900 may continue to a step 950. If the total power draw is below the threshold (“Yes” at 940), the operations 900 may continue to the step 950. If the rack controller 800 has initiated the modules 100 to the intermediate state but without applying full power, the rack controller 800 may provide full power to the modules 100 at this point.

During normal runtime operation, the operations may include conveying (950) data between the module(s) and/or a computing system. In addition, the rack controller 800 may periodically poll each module connector (e.g., using the module detect pin) to determine whether a module is still connected and/or whether a new module has been added. The operations may include determining (955) whether a module has been added or removed. If so (“Yes” at 955), the operations 900 may proceed to a step 960. If a module 100 has been removed, the rack controller 800 may shut off power to the module connector 510 from which that module 100 has been removed. If a module 100 has been added, the rack controller 800 may detect the new module 100 via the module 100 via the module detect pin and read the power requirements for the new module 100 using the procedure described above. If not (“No” at 955), the operations 900 may return to a step 950 and continue with normal runtime operation. Similarly, the operations may include determining (965) whether the power draw of the rack system 500 is within the power budget limits. For example, the total current draw may change if a module is added, removed, or replaced with a different module, if a module malfunctions, or if one or more modules begin drawing more power than during the power-on sequence. If power draw is within limits (“Yes” at 965), the operations 900 may return to a step 950 and continue with normal runtime operation. If the power draw is found to not be within limits (“No” at 965), the operations 900 may proceed to the step 960, with the rack system 500 illuminating an indicator and/or notifying the computing device of the potential overcurrent condition.

The result of a hot-swap (“Yes” at 955) and/or an overpower scenario (“No” at 965) may result in the rack controller 800 outputting a notification via the indicator(s) 695 and/or to the computer system via the external connector 680. The rack controller 800 may also turn off power to that rack position (e.g., the corresponding module connector 510). Accordingly, the operations 900 may include illuminating (960) the indicator and/or sending an indication to the computing device that the rack system configuration has been changed and/or that an overcurrent situation has been detected. In various implementations, the operations 900 may include more, fewer, and/or different steps than those illustrated in FIG. 9. Furthermore, certain steps may be performed multiple times, in a different order, and/or in parallel.

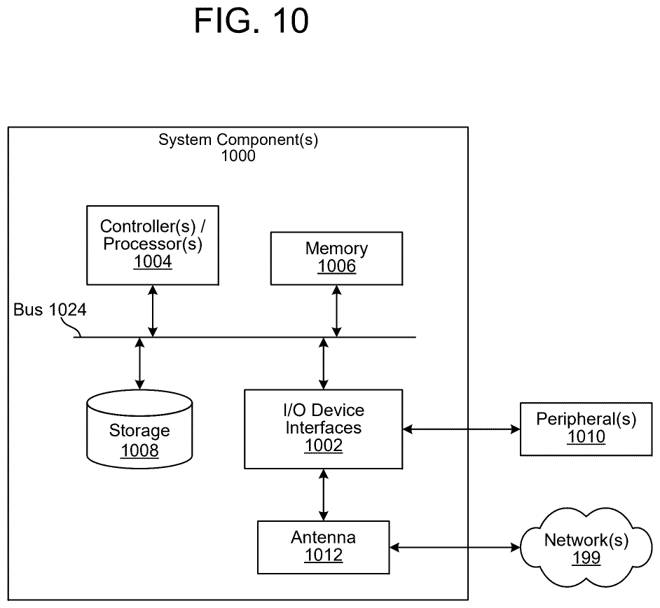

FIG. 10 is a block diagram conceptually illustrating example components of a computer system component 1000, according to embodiments of the present disclosure. One or more computer system components 1000 may be used to implement one or more of the computing devices described herein. The computer system components 1000 may correspond to a personal computer such as a desktop or laptop computer, a personal device such as a smartphone or tablet, and/or a cloud computing resource such as a server. A “server” as used herein may refer to a traditional server as understood in a server/client computing structure but may also refer to a number of different computing components that may assist with the operations discussed herein. For example, a server may include one or more physical computing components (such as a rack server) that are connected to other devices/components either physically and/or over a network and is capable of performing computing operations. A server may also include one or more virtual machines that emulates a computer system and is run on one or across multiple devices. A server may also include other combinations of hardware, software, firmware, or the like to perform operations discussed herein. The server(s) may be configured to operate using one or more of a client-server model, a computer bureau model, grid computing techniques, fog computing techniques, mainframe techniques, utility computing techniques, a peer-to-peer model, sandbox techniques, or other computing techniques. In some implementations, the operations described herein may be performed on one or a combination of different (and/or different types of) computer system components 1000.

Various computer system components 1000 may communicate with each other and/or with other computer systems and/or data sources via one or more computer networks 199 via a wireless local area network (WLAN) (such as Wi-Fi) radio, Bluetooth, and/or wireless network radio, such as a radio capable of communication with a wireless communication network such as a Long-Term Evolution (LTE) network, WiMAX network, 3G network, 4G network, 5G network, etc. A wired connection such as USB, I²C, I³C, Ethernet, etc., may also be supported. Through the computer network(s) 199, the system may be distributed across a networked environment.

A computer system component 1000 may include one or more controllers/processors 1004, which may each include a central processing unit (CPU) for processing data and computer-readable instructions, and a memory 1006 for storing data and instructions of the respective device. The controller(s)/processor(s) 1004 may include, for example, a microcontroller, microprocessor, system on chip (SoC), application-specific integrated circuit (ASIC), etc. The memories 1006 may individually include volatile random-access memory (RAM), non-volatile read only memory (ROM), non-volatile magnetoresistive memory (MRAM), and/or other types of memory. A computer system component 1000 may also include a data storage component 1008 for storing data and controller/processor-executable instructions. A data storage component 1008 may individually include one or more non-volatile storage types such as magnetic storage, optical storage, solid-state storage, etc. A computer system component 1000 may also be connected to removable or external non-volatile memory and/or storage (such as a removable memory card, memory key drive, networked storage, etc.) through respective input/output device interfaces 1002.

Computer instructions for operating a computer system component 1000 and its various components may be executed by the respective device's controller(s)/processor(s) 1004, using the memory 1006 as temporary “working” storage at runtime. A system's computer instructions may be stored in a non-transitory manner in non-volatile memory 1006, data storage component 1008, or an external device(s). Alternatively, some or all of the executable instructions may be embedded in hardware or firmware on the respective device in addition to or instead of software.

A computer system component 1000 may include input/output device interfaces 1002. A variety of peripheral components 1010 may be connected through the input/output device interfaces 1002, as will be discussed further below. Additionally, a computer system component 1000 may include an address/data bus 1024 for conveying data among components of the respective device. A component within a computer system component 1000 may also be directly connected to other components in addition to (or instead of) being connected to other components across the address/data bus 1024.

A computer system component 1000 may include input/output device interfaces 1002 that connect to a variety of peripheral components 1010; for example, an audio output component such as a speaker, a wired headset or a wireless headset (not illustrated), or other component capable of outputting audio. The peripheral components 1010 may also include an audio capture component. The audio capture component may be, for example, a microphone or array of microphones, a wired headset or a wireless headset (not illustrated), etc. If an array of microphones is included, approximate distance to a sound's point of origin may be determined by acoustic localization based on time and amplitude differences between sounds captured by different microphones of the array. The peripheral components 1010 may additionally include a display for displaying content. The peripheral components 1010 may further include a camera or cameras for receiving image and/or video content. The peripheral components 1010 may include converters for interfacing with audio equipment such as one or more of a digital audio workstation (DAW), digital-to-analog convertor, and/or analog-to-digital convertor. The peripheral components 1010 may include controllers, sequencers, keyboards, buttons, input or output expanders, and/or adaptors for interfacing with various audio equipment via MIDI, CV and gate, and/or other protocols.

Via antenna(s) 1012, the input/output device interfaces 1002 may connect to one or more networks 199 via a wireless local area network (WLAN) (such as Wi-Fi) radio, Bluetooth, and/or wireless network radio, such as a radio capable of communication with a wireless communication network such as a Long-Term Evolution (LTE) network, WiMAX network, 3G network, 4G network, 5G network, etc. A wired connection such as USB, I²C, I³C, Ethernet, etc., may also be supported. Through the network(s) 199, the system may be distributed across a networked environment. The I/O device interface 1002 may also include communication components that allow data to be exchanged between devices such as different physical servers in a collection of servers or other components.

As noted above, multiple computer system components 1000 may be employed in a single system. In such a multi-system environment, each of the computer system components 1000 may include different components for performing different aspects of the system's processing. The multiple devices may include overlapping components. The components of a computer system component 1000, as described herein, are illustrative, and may be located as a stand-alone device or may be included, in whole or in part, as a component of a larger device or system.

What is claimed is:

1. A rack for receiving modular equipment, the rack comprising:
a first upper rail;
a first lower rail;
a first lateral arm having a first end attached to a first end of the first upper rail and a second end attached to a first end of the first lower rail;
a second lateral arm having a first end attached to a second end of the first upper rail and a second end attached to a second end of the first lower rail, the first upper rail, lower rail, the first lateral arm, and the second lateral arm forming a first rack pane having:
an internal height measured in a direction parallel to a length of the first lateral arm and the second lateral arm, the internal height corresponding to a standardized height of the modular equipment, and
a first internal width measured in a direction parallel to a length of the first upper rail and the lower rail, the first internal width corresponding to a first integer multiple of a standardized width of the modular equipment;
at least a first module connector configured to, when a first module is mounted to the first rack pane, make electrical contact with a first connector of the first module; and
a first electronic component configured to, when the first module is mounted to the first rack pane, output first data representing a first location of the first module with respect to the first rack pane.

2. The rack of claim 1, further comprising:
a second upper rail, a second lower rail, a third lateral arm, and a fourth lateral arm forming a second rack pane having a second internal width corresponding to the first internal width;
a first joint forming a mechanical connection between the first lateral arm and the third lateral arm; and
a second joint forming a mechanical connection between the second lateral arm and the fourth lateral arm.

3. The rack of claim 2, further comprising:
a threaded screw hole defined in the first lateral arm; and
a plurality of detents arranged radially around the threaded screw hole, the first joint including a protrusion configured to extend at least partially into one of the plurality of detents.

4. The rack of claim 3, further comprising:
a hole defined in the first joint; and
a thumb screw configured to, when inserted through the hole and screwed into the threaded screw hole, push the protrusion into one of the plurality of detents and prevent rotational movement, of the first joint with respect to the first lateral arm about an axis of the thumb screw.

5. The rack of claim 2, further comprising:
a third upper rail, a third lower rail, a fifth lateral arm, and a sixth lateral arm forming a third rack pane having a third internal width corresponding to the first internal width;
a third joint forming a mechanical connection between the third lateral arm and the fifth lateral arm;
a fourth joint forming a mechanical connection between the fourth lateral arm and the sixth lateral arm; and
a handle/stand assembly removably attached to the rack.

6. The rack of claim 5, wherein:
the first joint, the second joint, the third joint, and the fourth joint are configured to allow the first rack pane, the second rack pane, and the third rack pane to fold with respect to each other such that the first rack pane is facing the third rack pane, and the first rack pane and the third rack pane are substantially parallel, and
the handle/stand assembly is configured to removably attach to the first rack pane and the second rack pane for transporting the rack.

7. The rack of claim 5, wherein the handle/stand assembly is configured to removably attach to the third lateral arm and the fourth lateral arm to support the rack for use of modular equipment mounted to the rack.

8. The rack of claim 1, further comprising:
a first screw removably attaching the first lateral arm to the first upper rail;
a second screw removably attaching the second lateral arm to the first upper rail;
a third screw removably attaching the first lateral arm to the first lower rail; and
a fourth screw removably attaching the second lateral arm to the first lower rail.

9. The rack of claim 8, wherein the first upper rail and the first lower rail can be replaced with a second upper rail and a second lower rail to form a second rack pane having a second internal width corresponding to a second integer multiple, different from the first integer multiple, of the standardized width.

10. The rack of claim 1, further comprising:
a first plurality of threaded screw holes defined in the first upper rail; and
a second plurality of threaded screw holes defined in the first lower rail, the first plurality of threaded screw holes and the second plurality of threaded screw holes arranged according to the standardized height and the standardized width to allow mounting of one or more modules to the first rack pane.

11. The rack of claim 1, further comprising one or more processors configured to:
when the first module is mounted to the rack, receive, from the first module via the first module connector, second data representing an identity of the first module; and
output, via a cable connector of the rack, third data representing the identity of the first module.

12. The rack of claim 1, further comprising one or more processors configured to:
receive the first data from the first electronic component;
when a second module is mounted to the rack, receive, from a second electronic component corresponding to a second module connector, second data representing a second location of the second module; and
output, via a cable connector of the rack, third data representing the first location and the second location.

13. The rack of claim 1, further comprising one or more processors configured to:
receive an indication to provide power to the modular equipment;
cause, at a first time, an electric voltage to be applied to the first module connector; and
cause, at a second time after the first time, the electric voltage to be applied to a second module connector.

14. The rack of claim 13, wherein the one or more processors are further configured to:
after causing the electric voltage to be applied to the first module connector, determining a first current consumption corresponding to the first module connector; and
determine that the first current consumption is below a threshold, wherein causing the electric voltage to be applied to the second module connector is subject to determining that the first current consumption is below the threshold.

15. The rack of claim 14, wherein the one or more processors are further configured to:
after causing the electric voltage to be applied to the second module connector, determining a second current consumption corresponding to the second module connector;
determine that a sum of the first current consumption and the second current consumption is below the threshold; and
in response to determining that the sum of the first current consumption and the second current consumption is below the threshold, cause the electric voltage to be applied to a third module connector.

16. The rack of claim 14, wherein the one or more processors are further configured to:
after causing the electric voltage to be applied to the second module connector, determining a second current consumption corresponding to the second module connector;
determine that a sum of the first current consumption and the second current consumption exceeds a threshold; and
in response to determining that the sum of the first current consumption and the second current consumption exceeds the threshold, prevent the electric voltage from being applied to a third module connector.

17. A module configured for standalone use or mounting to a rack having standardized dimensions, the module comprising:
a body;
an upper mounting rail protruding from a first edge of the body and extending along the first edge, the upper mounting rail defining a first screw hole at a first end of the upper mounting rail and a second screw hole at a second end of the upper mounting rail opposite the first end, wherein a first distance between the first screw hole and the second screw hole corresponds to an integer multiple of a standardized width;
a lower mounting rail protruding from a second edge of the body opposite the first edge, the lower mounting rail defining a third screw hole at a first end of the lower mounting rail and a fourth screw hole at a second end of the lower mounting rail opposite the first end, wherein a second distance between the first screw hole and the second screw hole corresponds to a integer multiple of a standardized width, a third distance between the first screw hole and the third screw hole corresponds to a standardized height, and a fourth distance between the second screw hole and the fourth screw hole corresponds to the standardized height; and
a first connector configured to, upon mounting of the module to the rack, make electrical contact with a first module connector of the rack.

18. The module of claim 17, further comprising:
a second connector configured to receive an electrical cable, wherein:
the first connector is arranged on one of the upper mounting rail or the lower mounting rail, and
the second connector is arranged on the body such that it can receive a cable when the module is mounted to the rack.

19. The module of claim 17, wherein the lower mounting rail defines:
a first rounded corner corresponding to the first end, the first rounded corner having a first radius parallel to a plane extending from the upper mounting rail to the lower mounting rail, and
a second rounded corner corresponding to the second end, the second rounded corner having a second radius parallel to the plane.

20. The module of claim 17, further comprising:
a stand configured to support the module at an angle with respect to a surface upon which the module is placed, the stand removably attached to at least one of:
(a) the upper mounting rail via the first screw hole and the second screw hole, or
(b) the lower mounting rail via the third screw hole and the fourth screw hole.
